(19) United States
(12) Patent Application Publication
(10) Pub. No.: US 2024/0194647 A1
(43) Pub. Date: Jun. 13, 2024

(54) SEMICONDUCTOR DEVICE AND METHOD FOR MANUFACTURING SEMICONDUCTOR DEVICE

(71) Applicant: Kioxia Corporation, Tokyo (JP)

(72) Inventors: Yuki SATO, Fujisawa Kanagawa (JP); Tsukasa KONNO, Yokohama Kanagawa (JP)

(73) Assignee: Kioxia Corporation, Tokyo (JP)

(21) Appl. No.: 18/463,792

(22) Filed: Sep. 8, 2023

(30) Foreign Application Priority Data
Dec. 12, 2022 (JP) 2022-197857

(51) Int. Cl. H01L 25/065; H01L 21/683; H01L 23/10; H01L 23/498

(52) U.S. Cl. CPC H01L 25/0657; H01L 21/6836; H01L 23/10; H01L 23/49816; H01L 2225/06506

(57) ABSTRACT

A semiconductor device includes: a substrate; a first semiconductor chip; a first bonding pad; a second semiconductor chip arranged between the substrate and the first semiconductor chip; a second bonding pad; a first insulating film; a bonding wire that connects the substrate, the first bonding pad, and the second bonding pad; and a sealing resin that seals at least the first semiconductor chip, the second semiconductor chip, and the bonding wire. The second semiconductor chip includes a first surface that faces the substrate, and a second opposite surface. The second surface includes a first bonding region where the second bonding pad and the first insulating film are arranged, and a first lamination region that has a first low-level surface formed lower than a surface of the first insulating film, the first semiconductor chip arranged on or above at least a part of the first low-level surface.

### CROSS-REFERENCE TO RELATED APPLICATION

This application is based upon and claims the benefit of priority from Japanese Patent Application No. 2022-197857, filed on Dec. 12, 2022, the entire contents of which are incorporated herein by reference.

### BACKGROUND OF THE INVENTION

### Field of the Invention

The embodiment relates to a semiconductor device and a method for manufacturing a semiconductor device.

### Description of the Related Art

Among semiconductor devices, there is a semiconductor device in which a plurality of laminated semiconductor chips is mounted on a mounted substrate.

### BRIEF DESCRIPTION OF THE DRAWINGS

FIG. 1 is a schematic view showing a cross-section of a semiconductor device according to a first embodiment as viewed laterally;

FIG. 2 is a plan view of a semiconductor chip according to the first embodiment as viewed from above;

FIG. 3 is a schematic view showing a cross-section of a semiconductor device according to a comparative example as viewed laterally;

FIG. 4 is a flowchart showing an exemplary method for manufacturing the semiconductor device according to the first embodiment;

FIG. 5A is a schematic view showing a production process for the semiconductor device according to the first embodiment;

FIG. 5B is a schematic view showing a production process for the semiconductor device according to the first embodiment;

FIG. 5C is a schematic view showing a production process for the semiconductor device according to the first embodiment;

FIG. 5D is a schematic view showing a production process for the semiconductor device according to the first embodiment;

FIG. 5E is a schematic view showing a production process for the semiconductor device according to the first embodiment;

FIG. 5F is a schematic view showing a production process for the semiconductor device according to the first embodiment;

FIG. 5G is a schematic view showing a production process for the semiconductor device according to the first embodiment;

FIG. 5H is a schematic view showing a production process for the semiconductor device according to the first embodiment;

FIG. 5I is a schematic view showing a production process for the semiconductor device according to the first embodiment;

FIG. 6 is a schematic view showing a cross-section of a semiconductor device according to a second embodiment as viewed laterally;

FIG. 7 is a plan view of a semiconductor chip according to the second embodiment as viewed from above;

FIG. 8 is a schematic view showing a cross-section of a semiconductor device according to a comparative example as viewed laterally;

FIG. 9 is a schematic view showing a cross-section of the semiconductor device according to the comparative example as viewed laterally;

FIG. 10 is a schematic view showing a production process for the semiconductor device according to the second embodiment;

FIG. 11 is a plan view of a semiconductor chip according to a first modification of the second embodiment as viewed from above;

FIG. 12 is a schematic view showing a cross-section of a semiconductor device according to a second modification of the second embodiment as viewed laterally;

FIG. 13 is a plan view of a semiconductor chip according to a third modification of the second embodiment as viewed from above;

FIG. 14 is a plan view of a semiconductor chip according to a fourth modification of the second embodiment as viewed from above;

FIG. 15 is a cross-section view along cutting-plane line XV-XV shown in FIG. 14;

FIG. 16 is a cross-section view along cutting-plane line XV-XV shown in FIG. 14;

FIG. 17 is a cross-section view along cutting-plane line XV-XV shown in FIG. 14;

FIG. 18 is a cross-section view along cutting-plane line XV-XV shown in FIG. 14; and

FIG. 19 is a schematic view showing a cross-section of a semiconductor device according to a modification as viewed laterally.

### DETAILED DESCRIPTION OF THE PREFERRED EMBODIMENTS

Embodiments will be described below with reference to the accompanying drawings. For facilitating understanding of descriptions, in the drawings, identical constituent elements are denoted by identical reference characters as much as possible, and repetitive descriptions are omitted.

### First Embodiment

The configuration of a semiconductor device according to a first embodiment will be described below. In some of the drawings, an X-axis, a Y-axis, and a Z-axis are shown. The X-axis, the Y-axis, and the Z-axis form three-dimensional orthogonal coordinates in a right-handed system. Hereinafter, the direction of the arrow of the X-axis is occasionally referred to as an X-axis+direction, and the opposite direction of the arrow is occasionally referred to as an X-axis−direction. The same goes for the other axes. The Z-axis+direction and the Z-axis−direction are occasionally referred to as “upper direction” and “lower direction”, respectively. A plane orthogonal to the X-axis, the Y-axis, or the Z-axis is occasionally referred to as a YZ plane, a ZX plane, or an XY plane, respectively.

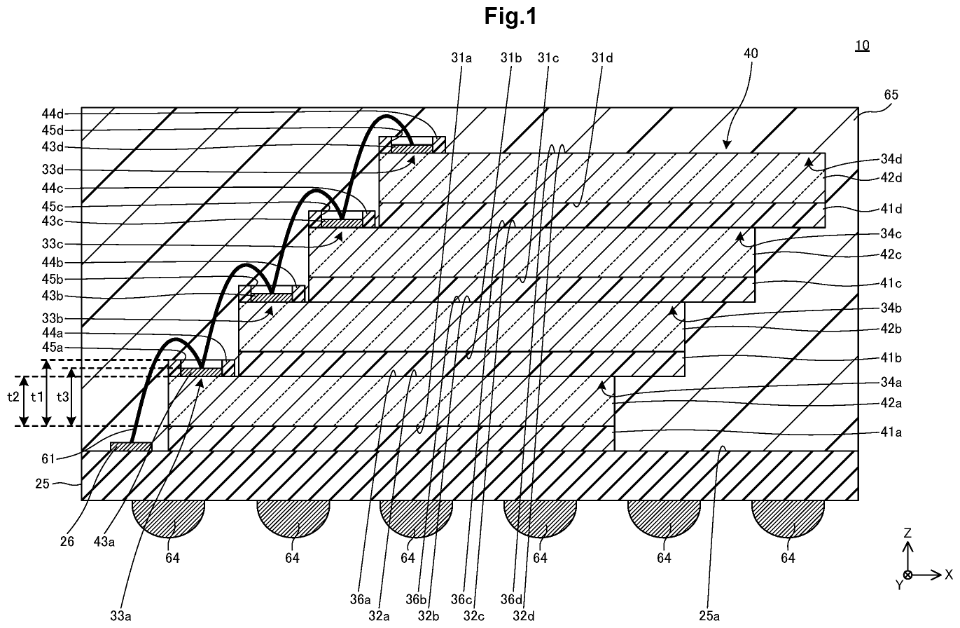

FIG. 1 is a schematic view showing a cross-section of the semiconductor device according to the first embodiment, which is a cross-section parallel to the ZX plane. As shown in FIG. 1, a semiconductor device 10 (an example of the “semiconductor memory device”) includes a wiring substrate 25 (an example of the “substrate”), a chip laminated body 40, bonding wires 61, and a sealing resin 65.

The chip laminated body 40 includes die attach films 41a, 41b (an example of the “adhesion layer”), 41c and 41d that are resin layers, semiconductor chips 42a (an example of the “second semiconductor chip”), 42b (an example of the “first semiconductor chip”), 42c (an example of the “third semiconductor chip”) and 42d, chip electrodes 43a (an example of the “second bonding pad”), 43b (an example of the “first bonding pad”), 43c and 43d, and PI (polyimide) films 44a (an example of the “first insulating film”), 44b (an example of the “second insulating film”), 44c and 44d.

Hereinafter, each of the die attach films 41a, 41b, 41c, and 41d is occasionally referred to as a die attach film 41. Each of the semiconductor chips 42a, 42b, 42c, and 42d is occasionally referred to as a semiconductor chip 42. Each of the chip electrodes 43a, 43b, 43c, and 43d is occasionally referred to as a chip electrode 43. Each of the PI films 44a, 44b, 44c, and 44d is occasionally referred to as a PI film 44.

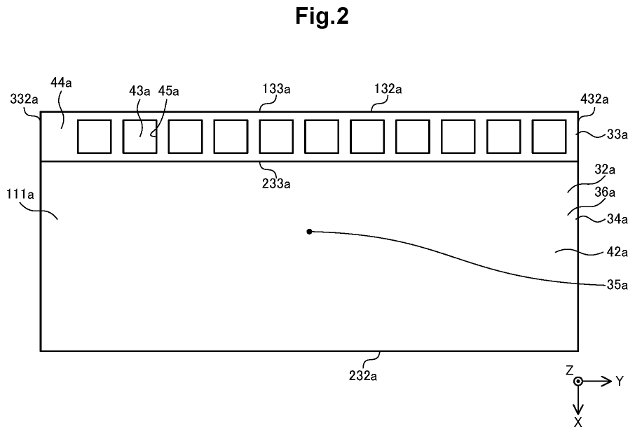

FIG. 2 is a plan view of the semiconductor chip 42a as viewed from above. The configurations of the semiconductor chips 42b to 42d are the same as the configuration of the semiconductor chip 42a. Accordingly, the configuration of the semiconductor chip 42a will be described in detail, and the configurations of the semiconductor chips 42b to 42d will be briefly described.

As shown in FIG. 1 and FIG. 2, for example, the semiconductor chip 42 is a NAND flash memory chip. The semiconductor chip 42 may be a DRAM chip, or may be a chip having another function.

The shape of the semiconductor chip 42a is a plate shape in which an upper side and lower side are respectively planes 31a (an example of the “first surface”) and 32a (an example of the “second surface”) roughly parallel to the XY plane. The planes 31a and 32a have a roughly rectangular shape. The short sides and long sides of the rectangular shape are roughly parallel to the X-axis and the Y-axis, respectively.

Hereinafter, of the two facing long sides of the plane 32a, the side in the X-axis−direction and the side in the X-axis+direction are occasionally referred to as a side 132a and a side 232a, respectively. Of the two facing short sides of the plane 32a, the side in the Y-axis−direction and the side in the Y-axis+direction are occasionally referred to as a side 332a and a side 432a, respectively.

The plane 31a of the semiconductor chip 42a faces an upper plane 25a of the wiring substrate 25 across the die attach film 41a.

For example, the plane 31a has been smoothed by grinding described later. For example, a storage circuit 111a (an example of the “memory circuit”) is formed on the plane 32a on the opposite side of the plane 31a. The outermost surface of a portion where the storage circuit 111a is formed may be covered with an inorganic film composed of silicon nitride, silicon dioxide, or the like. Alternatively, the outermost surface of the portion where the storage circuit 111a is formed may be covered with an organic film.

The plane 32a includes a bonding region 33a (an example of the “first bonding region”) and a lamination region 34a (an example of the “first lamination region”). The chip electrode 43a and the PI film 44a are arranged at the bonding region 33a.

In the embodiment, for example, the PI film 44a is a film for which photolithography processing can be performed, as exemplified by a photosensitive polyimide film. The PI film 44a is arranged around the chip electrode 43a, and covers the storage circuit 111a.

The outer shape of the bonding region 33a coincides with the outer shape of the region where the PI film 44a is formed. Specifically, the bonding region 33a has a rectangular shape that is long in the Y-axis direction, and is positioned so as to be closer to the side 132a than to the side 232a.

More specifically, the side 133a of the bonding region 33a in the X-axis−direction abuts on the side 132a. The side 233a of the bonding region 33a in the X-axis+direction is positioned in the X-axis−direction relative to a center 35a of the plane 32a. The side of the bonding region 33a in the Y-axis−direction and the side of the bonding region 33a in the Y-axis+direction abut on the sides 332a and 432a, respectively.

At the bonding region 33a, the plurality of chip electrodes 43a is arranged on a straight line roughly parallel to the Y-axis. More specifically, a plurality of hole portions 45a each of which has a rectangular cross-section and reaches the storage circuit 111a is formed on the PI film 44a by photolithography processing. The chip electrode 43a is a metal electrode that is formed in the hole portion 45a, and includes one end that is electrically connected to the storage circuit 111a and the other end that is an exposed surface to which the bonding wire 61 is connected.

The PI film 44a is formed so as to be higher than the chip electrode 43a (namely, the surface of the PI film 44a is formed that being higher than a surface of the second bonding pad). Accordingly, a thickness t1 of the semiconductor chip 42a at a portion where the PI film 44a is formed is larger than a thickness t3 of the semiconductor chip 42a at a portion where the chip electrode 43a is formed. That is, the exposed surface of the chip electrode 43a, namely, the other end is dented with respect to the PI film 44a.

The lamination region 34a that has the low-level surface 36a formed so as to be lower than a surface of the first insulating film The height of a surface (an example of the “first low-level surface”; occasionally referred to as a low-level surface 36a hereinafter) of the lamination region 34a on the plane 32a is lower than the height of the upper surface of the PI film 44a, and the semiconductor chip 42b is arranged on at least a part of the low-level surface 36a.

In the embodiment, on the plane 32a, the lamination region 34a is a region in the X-axis+direction relative to the side 233a. That is, the lamination region 34a is a region where neither the PI film 44a nor the chip electrode 43a is formed and where the storage circuit 111a is exposed. Therefore, a thickness t2 of the lamination region 34a is smaller than the thicknesses t1 and t3 of the bonding region 33a.

The die attach film 41a is arranged between the semiconductor chip 42a and the wiring substrate 25, and performs adhesion between the plane 31a of the semiconductor chip 42a and the plane 25a of the wiring substrate 25.

The semiconductor chip 42b includes a plane 31b (an example of the “third surface”) that faces the wiring substrate 25 across the semiconductor chip 42a, and a plane 32b (an example of the “fourth surface”) on the opposite side of the plane 31b. That is, the planes 31b and 32b are the lower plane and upper plane of the semiconductor chip 42b, respectively.

The plane 32b includes a bonding region 33b (an example of the “second bonding region”) and a lamination region 34b (an example of the “second lamination region”). The PI film 44b and the plurality of chip electrodes 43b are arranged on the bonding region 33b. The lamination region 34b has a low-level surface 36b (an example of the “second low-level surface”) formed so as to be lower than an upper surface of the PI film 44b (namely, the lamination region 34b has a low-level surface 36b formed that being lower than a surface of the second insulating film). The number of chip electrodes 43b that are provided is the same as the number of the chip electrodes 43a.

The die attach film 41b performs adhesion between at least a part of the lamination region 34a on the plane 32a and at least a part of the plane 31b.

In the embodiment, the die attach film 41b is arranged between the semiconductor chip 42a and the semiconductor chip 42b. There is a gap between the die attach film 41b and the PI film 44a positioned in the X-axis−direction of the die attach film 41b. Therefore, the die attach film 41b performs adhesion between a part of the lamination region 34a in the X-axis+direction and the plane 31b. It is allowable to adopt a configuration in which the die attach film 41b performs adhesion between the whole of the lamination region 34a and the plane 31b with no gap with the PI film 44a.

The configurations of the semiconductor chips 42c and 42d are the same as the configurations of the semiconductor chips 42a and 42b.

The die attach film 41c performs adhesion between an X-axis+directional part of the lamination region 34b on the plane 32b of the semiconductor chip 42b and a lower plane 31c of the semiconductor chip 42c. It is allowable to adopt a configuration in which the die attach film 41c performs adhesion between the whole of the lamination region 34b and the plane 31c with no gap with the PI film 44b.

The die attach film 41d performs adhesion between an X-axis+directional part of the lamination region 34c on a plane 32c of the semiconductor chip 42c and a lower plane 31d of the semiconductor chip 42d. It is allowable to adopt a configuration in which the die attach film 41d performs adhesion between the whole of the lamination region 34c and the plane 31d with no gap with the PI film 44c.

The wiring substrate 25 includes a plane 25a that faces the plane 31a of the semiconductor chip 42a. For example, the plane 25a has a rectangular shape. On the plane 25a, for example, in the X-axis−direction of the semiconductor chip 42a, a plurality of substrate electrodes 26 is arranged on a straight line roughly parallel to the Y-axis. The number of substrate electrodes 26 that are provided is the same as the number of the chip electrodes 43a.

The number of bonding wires 61 that are provided is the same as the number of the chip electrodes 43a. That is, the number of sets of the substrate electrode 26, the bonding wire 61, and the chip electrodes 43a, 43b, 43c, and 43d that are provided is the same as the number of the chip electrodes 43a. Each bonding wire 61 electrically connects the substrate electrode 26 and the chip electrodes 43a, 43b, 43c, and 43d in the set.

A plurality of solder balls 64 (an example of the “external terminal”) is arranged on a lower surface of the wiring substrate 25. Each of the plurality of solder balls 64 is electrically connected to a controller chip (not illustrated) through an electrode pattern (not illustrated) and a via (not illustrated), for example. For example, the controller chip is arranged on a lateral side of the chip laminated body 40, and operates by signals and electric power that are supplied from the exterior through the solder ball 64.

Each of the plurality of substrate electrodes 26 is electrically connected to a controller chip (not illustrated) through an electrode pattern (not illustrated), for example. The controller chip controls the semiconductor chip 42 by supplying a control signal to the semiconductor chip 42 through the substrate electrode 26 and the bonding wire 61.

The sealing resin 65 seals at least the semiconductor chips 42a, 42b, 42c, and 42d, and the bonding wires 61. Specifically, the chip laminated body 40 and the bonding wires 61 are buried in the sealing resin 65, on the wiring substrate 25. The chip laminated body 40 and the bonding wires 61 are sealed by the sealing resin 65 in an insulated manner.

### COMPARATIVE EXAMPLE

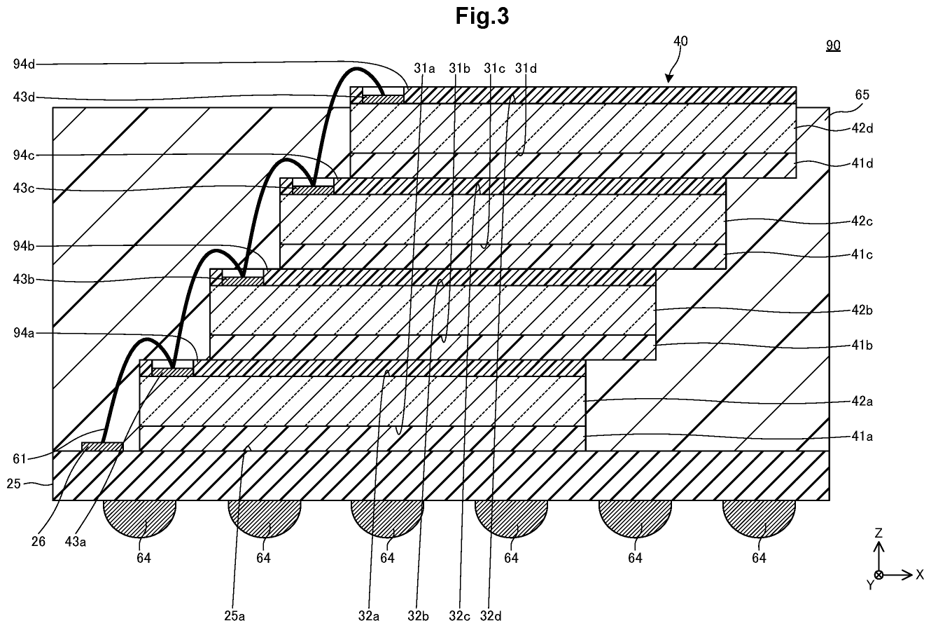

FIG. 3 is a schematic view showing a cross-section of a semiconductor device according to a comparative example as viewed laterally. When compared to the semiconductor device 10 shown in FIG. 1 and FIG. 2, as shown in FIG. 3, a semiconductor device 90 according to the comparative example includes PI films 94a to 94d, instead of the PI films 44a to 44d.

In the semiconductor device 90, the lamination region 34a is not provided on the upper plane 32a of the semiconductor chip 42a, and instead, the PI film 94a is arranged. The die attach film 41b performs adhesion between the lower plane 31b of the semiconductor chip 42b and an upper plane of the PI film 94a.

Similarly, the lamination regions 34b to 34d are not provided on the upper planes 32b to 32d of the semiconductor chips 42b to 42d, and instead, the PI films 94b to 94d are arranged. The die attach film 41c performs adhesion between the lower plane 31c of the semiconductor chip 42c and an upper plane of the PI film 94b. The die attach film 41d performs adhesion between the lower plane 31d of the semiconductor chip 42d and an upper plane of the PI film 94c.

That is, in the semiconductor device 90, the lamination region formed so as to be lower than the upper plane of the PI film is not provided. Therefore, the total height of the chip laminated body 40 is large. In contrast, in the semiconductor device 10 shown in FIG. 1, the semiconductor chips 42b to 42d are laminated on the lamination regions 34a to 34c having a small thickness, respectively, and thereby it is possible to reduce the total height of the chip laminated body 40. Thereby, it is possible to reduce the thickness of the sealing resin 65 in the semiconductor device 10, and further it is possible to reduce the whole thickness of the semiconductor device 10. Further, it is possible to shorten the distance among the semiconductor chips 42, and therefore it is possible to improve the heat dissipation of the semiconductor chips 42.

On the other hand, if the chip laminated body 40 and the bonding wires 61 in the semiconductor device 90 are sealed by a sealing resin 65 having the same thickness as the thickness of the sealing resin 65 in the semiconductor device 10, a part of the chip laminated body 40 and the bonding wire 61 are exposed from the sealing resin 65, in the semiconductor device 90.

Further, because of the configuration in which the PI film 44a is arranged around the chip electrode 43a, even if the bonding wire 61 is bent by external force, the bonding wire 61 can easily abut on the PI film 44a instead of the semiconductor chip 42a. Thereby, it is possible to reduce the possibility of the occurrence of electric short circuit.

### [Method for Manufacturing Semiconductor Device]

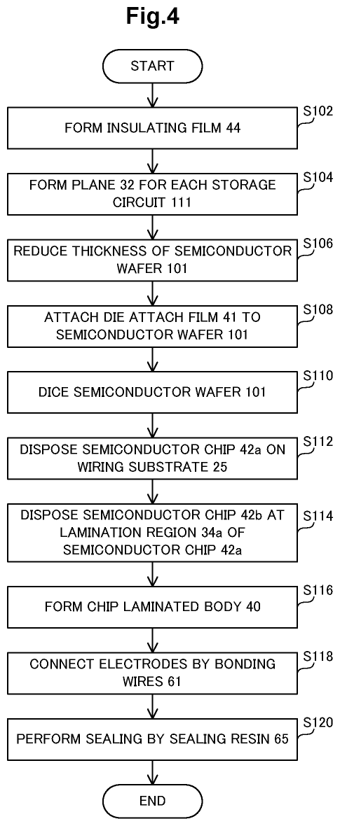

A method for manufacturing the semiconductor device 10 will be described below as an example of the method for manufacturing the semiconductor device according to the embodiment. FIG. 4 is a flowchart showing an exemplary method for manufacturing the semiconductor device according to the embodiment.

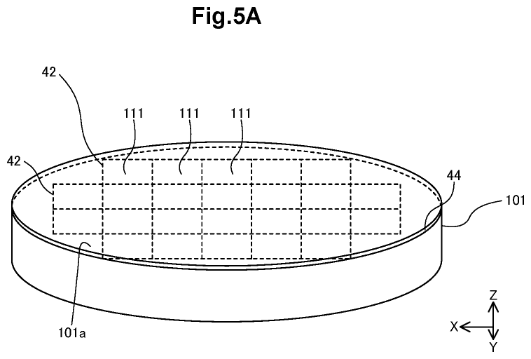

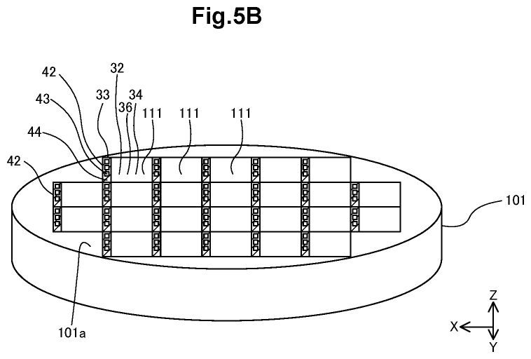

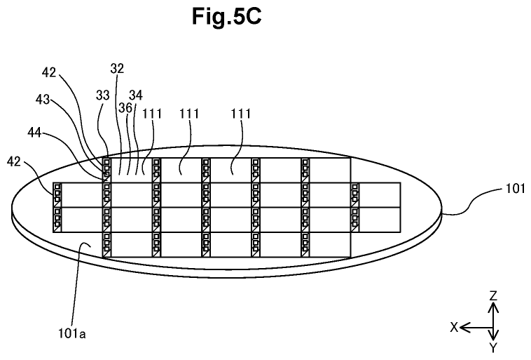

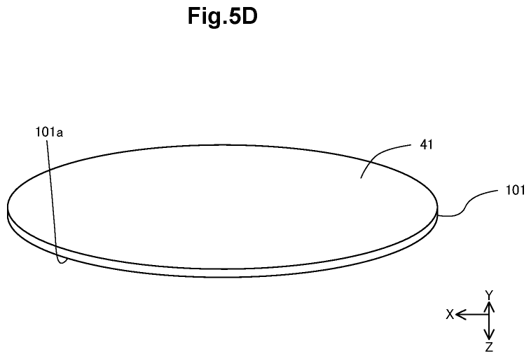

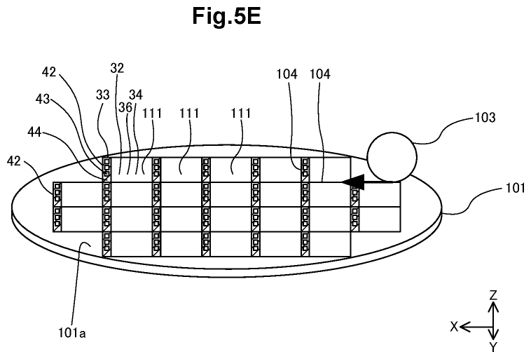

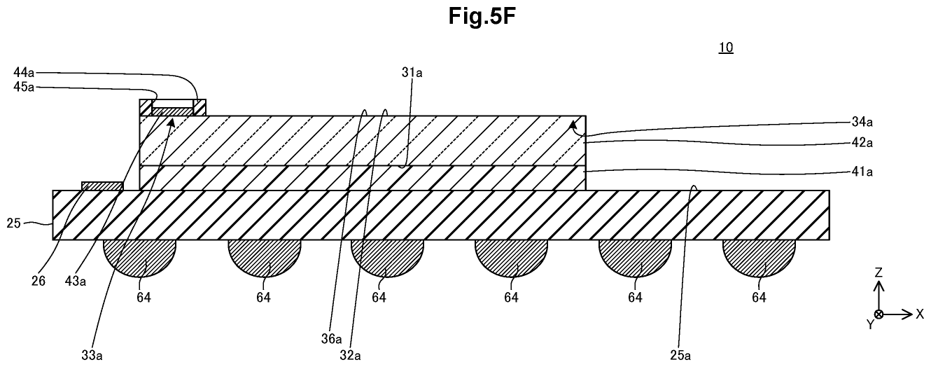

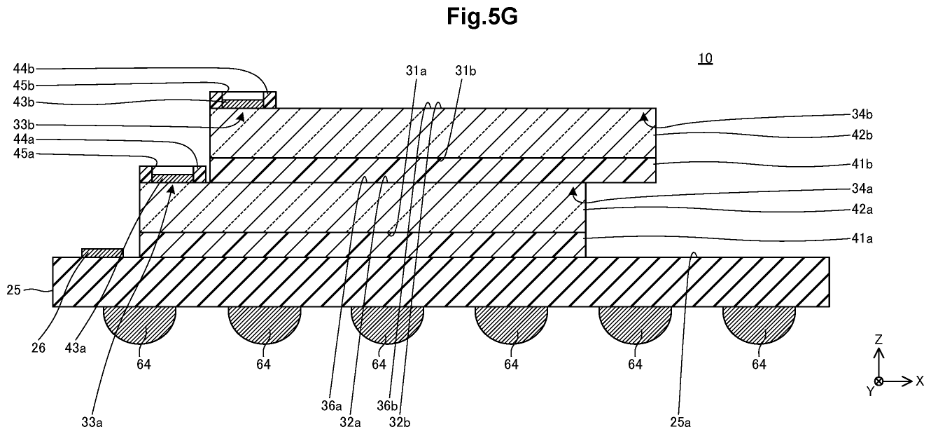

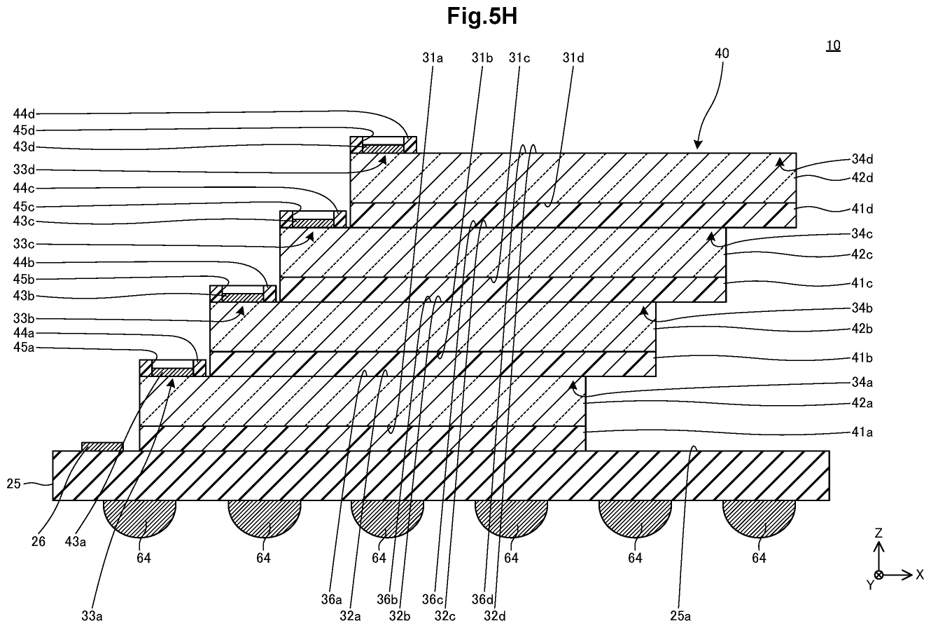

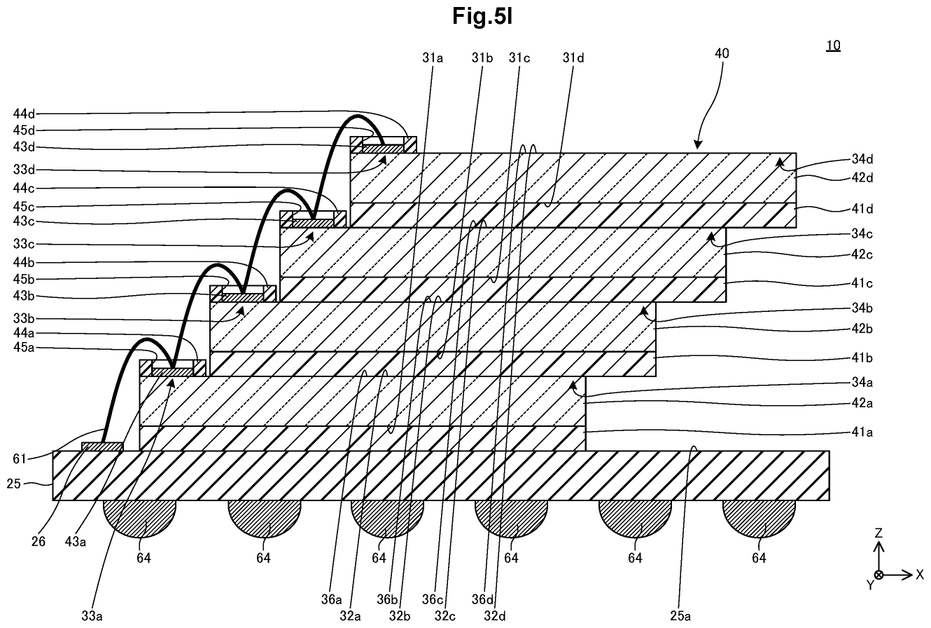

First, as shown in FIG. 4 and FIG. 5A, a PI film 44 (an example of the “insulating film”) is formed on a circuit plane 101a (an example of the “first plane”) on the upper side of a semiconductor wafer 101 on which a plurality of storage circuits 111 that is to be respectively included in a plurality of semiconductor chips 42 is formed (step S102).

Next, as shown in FIG. 4 and FIG. 5B, a plane 32 that is a part of the circuit plane 101a is formed for each storage circuit 111 (step S104). The plane 32 includes a bonding region 33 and a lamination region 34. A chip electrode 43 and a part of a PI film 44 are arranged at the bonding region 33. The lamination region 34 has a low-level surface 36 formed so as to be lower than the upper surface of the PI film 44 (namely, the lamination region 34 has a low-level surface 36 formed that being lower than a surface of the insulating film), and the semiconductor chip 42 can be arranged on at least a part of the low-level surface 36.

Specifically, by the photolithography processing of the PI film 44, the PI film 44 at a portion of the bonding region 33 where the chip electrode 43 is to be formed and the PI film 44 at the lamination region 34 are removed.

More specifically, the PI film 44 is exposed in a predetermined pattern, and thereafter extra PI films 44 are removed by wet etching. At this time, at least the PI film 44 at the above portion and the PI film 44 at the lamination region 34 are removed. Then, the PI film 44 is cured, and thereafter the chip electrode 43 is formed at the above portion.

Next, as shown in FIG. 4 and FIG. 5C, the thickness of the semiconductor wafer 101 is reduced by removing a lower portion of the semiconductor wafer 101 (step S106). Specifically, a lower plane of the semiconductor wafer 101 where the storage circuit 111 is not formed is ground by grinding stone. Thereby, the thickness of the semiconductor wafer 101 is reduced.

Next, as shown in FIG. 4 and FIG. 5D, a die attach film 41 is attached to a lower plane of the semiconductor wafer 101 (step S108).

Next, as shown in FIG. 4 and FIG. 5E, on the circuit plane 101a on the upper side of the semiconductor wafer 101, the semiconductor wafer 101 is diced by putting in a blade 103 along dicing lines 104 (step S110). The semiconductor wafer 101 is separated into a plurality of semiconductor chips 42.

Next, as shown in FIG. 4 and FIG. 5F, the semiconductor chip 42a, which is one of the plurality of semiconductor chips 42 separated from the semiconductor wafer 101, is disposed on the wiring substrate 25 (step S112). Specifically, the plane 31a of the semiconductor chip 42a is caused to adhere to the plane 25a of the wiring substrate 25, by the die attach film 41a.

Next, as shown in FIG. 4 and FIG. 5G, the semiconductor chip 42b, which is another one of the plurality of semiconductor chips 42 separated from the semiconductor wafer 101, is disposed at the lamination region 34a of the semiconductor chip 42a (step S114). Specifically, the plane 31b of the semiconductor chip 42b is caused to adhere to the lamination region 34a of the semiconductor chip 42a, by the die attach film 41b.

Next, as shown in FIG. 4 and FIG. 5H, similarly to the semiconductor chip 42b, the semiconductor chips 42c and 42d are disposed at the lamination region 34b of the semiconductor chip 42b and the lamination region 34c of the semiconductor chip 42c, respectively. Thereby, the chip laminated body 40 is formed (step S116).

Next, as shown in FIG. 4 and FIG. 5I, the substrate electrodes 26 and the chip electrodes 43a, 43b, 43c, and 43d on the wiring substrate 25 are electrically connected by the bonding wires 61 (step S118).

Next, as shown in FIG. 1 and FIG. 4, the chip laminated body 40 and the bonding wires 61 are sealed by the sealing resin 65 (step S120).

### Second Embodiment

A semiconductor device 12 according to a second embodiment will be described. In the second embodiments and subsequent embodiments, descriptions about matters in common with the first embodiment will be omitted, and only different points will be described. Particularly, the same function effects due to the same configurations will not be mentioned in all embodiments.

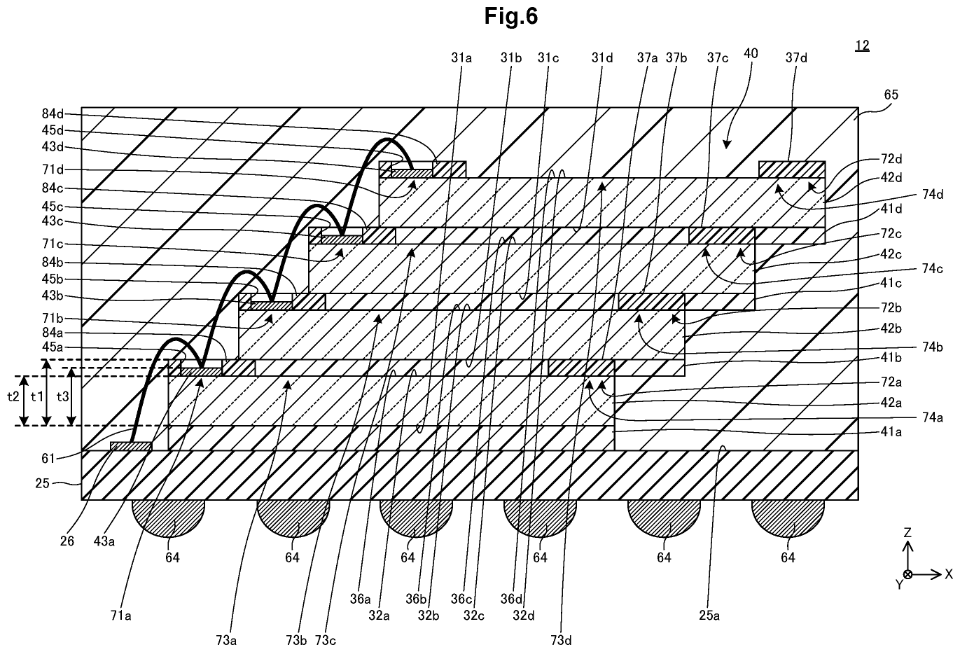

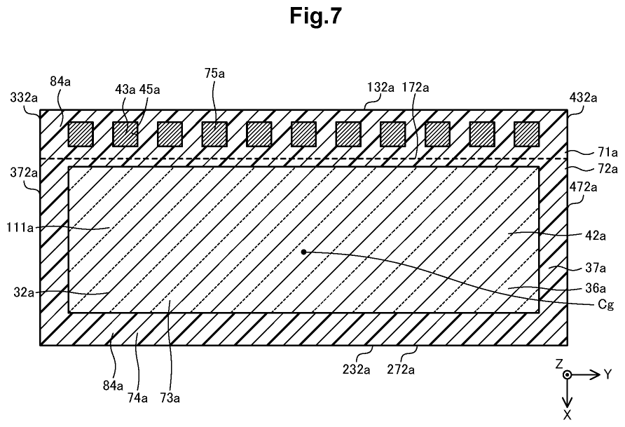

FIG. 6 is a schematic view showing a cross-section of the semiconductor device according to the second embodiment, which is a cross-section parallel to the ZX plane. FIG. 7 is a plan view of the semiconductor chip according to the second embodiment as viewed from above. As shown in FIG. 6 and FIG. 7, the semiconductor device 12 (an example of the “semiconductor memory device”) is different from the semiconductor device 10 shown in FIG. 1 and FIG. 2, in the shape of the region where the PI film is arranged.

The configurations of the semiconductor chips 42b to 42d are the same as the configuration of the semiconductor chip 42a. Accordingly, the configuration of the semiconductor chip 42a will be described in detail, and the configurations of the semiconductor chips 42b to 42d will be briefly described.

The upper plane 32a (an example of the “second surface”) of the semiconductor chip 42a includes a chip arrangement region 72a (an example of the “first chip arrangement region”) where the semiconductor chip 42b (an example of the “first semiconductor chip”) is arranged, and an adjacent region 71a that is adjacent to the chip arrangement region 72a (see FIG. 7).

In the embodiment, the chip arrangement region 72a is a region having a rectangular shape that is long in the Y-axis direction. An edge 172a of the chip arrangement region 72a in the X-axis−direction and an edge 272a of the chip arrangement region 72a in the X-axis+direction are roughly parallel to the Y-axis. An edge 372a of the chip arrangement region 72a in the Y-axis−direction and an edge 472a of the chip arrangement region 72a in the Y-axis+direction are roughly parallel to the X-axis.

The adjacent region 71a is positioned in the X-axis−direction of the chip arrangement region 72a, and is adjacent to the chip arrangement region 72a through the edge 172a. The adjacent region 71a is a region having a rectangular shape that is long in the Y-axis direction. The adjacent region 71a does not overlap with the chip arrangement region 72a.

That is, when the plane 32a is divided at the edge 172a into two regions, the region positioned in the X-axis+direction is the chip arrangement region 72a, and the region positioned in the X-axis−direction is the adjacent region 71a. Each shape of the adjacent region 71a and the chip arrangement region 72a is not limited to a rectangular shape, and may be an arbitrary shape.

The plane 32a includes a low-level surface region 73a, a high-level surface region 74a, and a plurality of chip electrode regions 75a.

The whole of the low-level surface region 73a overlaps with the chip arrangement region 72a. In the embodiment, the low-level surface region 73a includes a gravity center Cg of the chip arrangement region 72a. The low-level surface region 73a may be configured such that a part of the low-level surface region 73a overlaps with the chip arrangement region 72a. The low-level surface region 73a has a low-level surface 36a (an example of the “third low-level surface”) formed so as to be lower than a high-level surface 37a at the high-level surface region 74a.

Herein, the low-level surface region 73a (“lower surface area 73a”) means a surface region where the height from a reference position is less than a first height. The high-level surface region 74a (“higher surface area 74a”) means a surface region where the height from the reference position is equal to or more than the first height and is less than a second height (the second height is more than the first height). For example, the reference position means the upper surface of the semiconductor chip 42a, that is, the plane 32a. A low-level surface region including the low-level surface region 73a may be referred to as a first surface region where the height from the reference position is less than the first height. A high-level surface region including the high-level surface region 74a may be referred to as a second surface region where the height from the identical reference position is equal to or more than the first height and is less than the second height.

The low-level surface region 73a is a region having a rectangular shape that is long in the Y-axis direction. The low-level surface region 73a is a region where the upper surface of the semiconductor chip 42a is exposed. The shape of the low-level surface region 73a is not limited to a rectangular shape, and may be an arbitrary shape.

A PI film 84a (an example of the “first insulating film”) is arranged at the high-level surface region 74a. An upper plane of the PI film 84a is the high-level surface 37a. The high-level surface region 74a extends over the chip arrangement region 72a and the adjacent region 71a. A part of the high-level surface region 74a overlaps with the chip arrangement region 72a, and another part overlaps with the adjacent region 71a. It is allowable to adopt a configuration in which the whole of the high-level surface region 74a overlaps with a part of the chip arrangement region 72a.

The high-level surface region 74a is adjacent to the low-level surface region 73a. In the embodiment, the high-level surface region 74a surrounds the low-level surface region 73a. The high-level surface region 74a positioned so as to be closer to the edge 172a, 272a, 372a, or 472a of the chip arrangement region 72a than to the gravity center Cg. The high-level surface region 74a contacts with sides (an example of the “edge”) 132a, 232a, 332a, and 432a of the plane 32a, in planar view of the plane 32a.

The plurality of chip electrode regions 75a is included in the adjacent region 71a. Specifically, the plurality of chip electrode regions 75a is positioned so as to be arrayed roughly parallel to the Y-axis, in the adjacent region 71a. At the plurality of chip electrode regions 75a, the PI film 84a is not arranged, and the hole portions 45a are provided respectively. The chip electrodes 43a are arranged in the plurality of hole portions 45a, respectively. The surface of the PI film 84a is formed so as to be higher than the surface of the chip electrode 43a (namely, the surface of the PI film 84a is formed that being higher than a surface of the second bonding pad).

The die attach film 41b (an example of the “adhesion layer”) performs adhesion between at least a part of the low-level surface region 73a on the plane 32a and at least a part of the plane 31b on the semiconductor chip 42b (see FIG. 6). In the embodiment, at least a part of the upper plane of the PI film 84a, that is, at least a part of the high-level surface 37a, and the lower plane 31b of the semiconductor chip 42b contact with each other.

The plane 32b of the semiconductor chip 42b includes a chip arrangement region 72b (an example of the “second chip arrangement region”) where the semiconductor chip 42c (an example of the “third semiconductor chip”) is arranged, and an adjacent region 71b that is adjacent to the chip arrangement region 72b.

The chip arrangement region 72b and the adjacent region 71b are the same as the chip arrangement region 72a and the adjacent region 71a on the plane 32a of the semiconductor chip 42a, respectively.

Further, the plane 32b includes a low-level surface region 73b, a high-level surface region 74b, and a plurality of chip electrode regions 75b. The low-level surface region 73b, the high-level surface region 74b, and the chip electrode region 75b are the same as the low-level surface region 73a, the high-level surface region 74a, and the chip electrode region 75a on the plane 32a of the semiconductor chip 42a, respectively.

A PI film 84b arranged at the high-level surface region 74b is the same as the PI film 84a arranged at the high-level surface region 74a of the semiconductor chip 42a.

### Effects

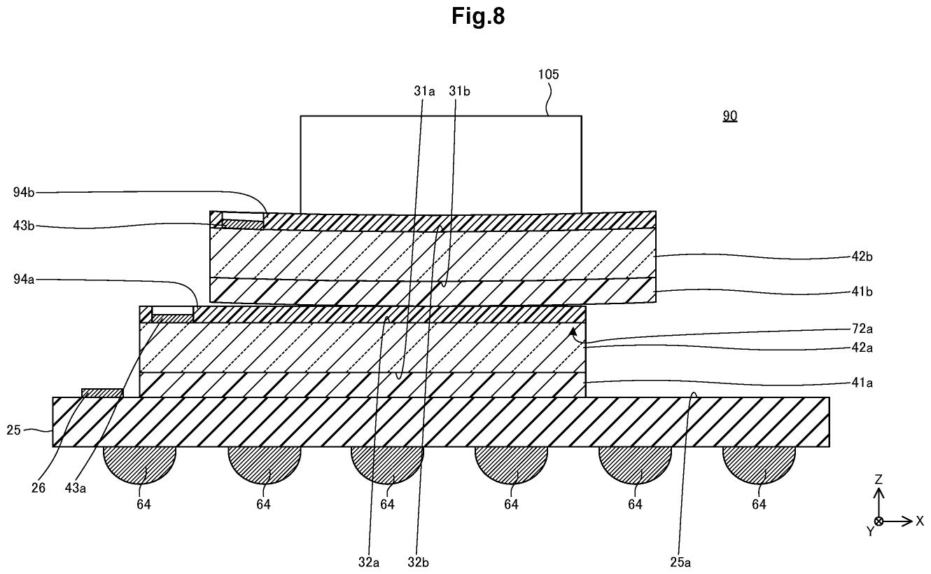

As shown in FIG. 8, in the method for manufacturing the semiconductor device 90, when the semiconductor chip 42b is placed on the semiconductor chip 42a, the semiconductor chip 42b is transported by a bonding collet 105, for example. Then, the semiconductor chip 42b is pressed onto the semiconductor chip 42a by the bonding collet 105.

In the case where the low-level surface region 73a is not included on the plane 32a and the PI film 94a is arranged over the whole of the chip arrangement region 72a instead of the PI film 84a as shown in FIG. 8, the following problem occasionally occurs.

In the case where the contact area between the bonding collet 105 and the semiconductor chip 42b is smaller than the area of the upper plane 32b of the semiconductor chip 42b, when the bonding collet 105 presses the semiconductor chip 42b downward, an end portion of the semiconductor chip 42b is occasionally turned upward.

At this time, a portion that is not buried by the die attach film 41b, that is, a gap is occasionally formed between the semiconductor chip 42b and the PI film 94a. Further, there is a possibility that an air bubble or a void is formed in the die attach film 41b. As the thickness of the semiconductor chip 42b is smaller, the turning becomes more conspicuous and the gap, the air bubble, the void, or the like is more easily generated.

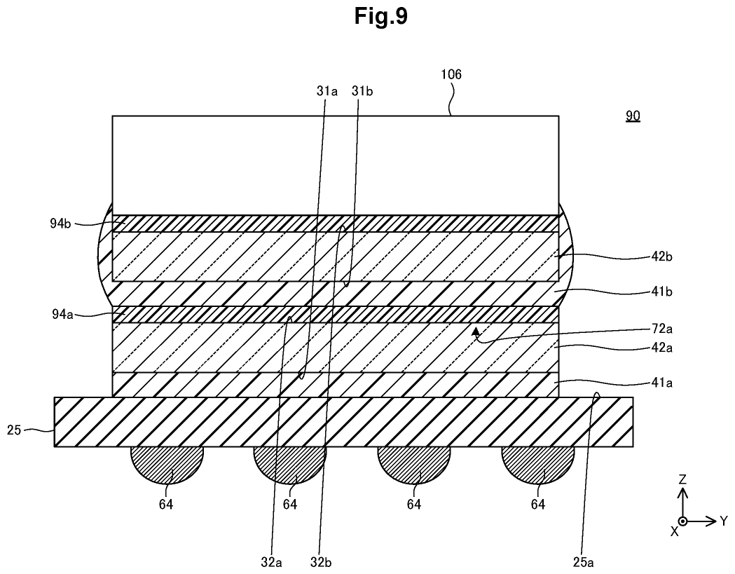

Further, as shown in FIG. 9, a bleed phenomenon in which the die attach film 41b crawls upward by the pressure for the adhesion of the semiconductor chip 42b occurs. For example, in the case where a bonding collet 106 that presses the whole of the upper plane 32b of the semiconductor chip 42b is used, the bonding collet 106 occasionally gets contact with the crawling die attach film 41b and the die attach film 41 occasionally adheres to the bonding collet 106.

In the case where another semiconductor chip 42 (for example, the semiconductor chip 42c) is pressed by the bonding collet 106 to which the die attach film 41 adheres, the risk of the transfer of the die attach film 41 to the semiconductor chip 42c can become high.

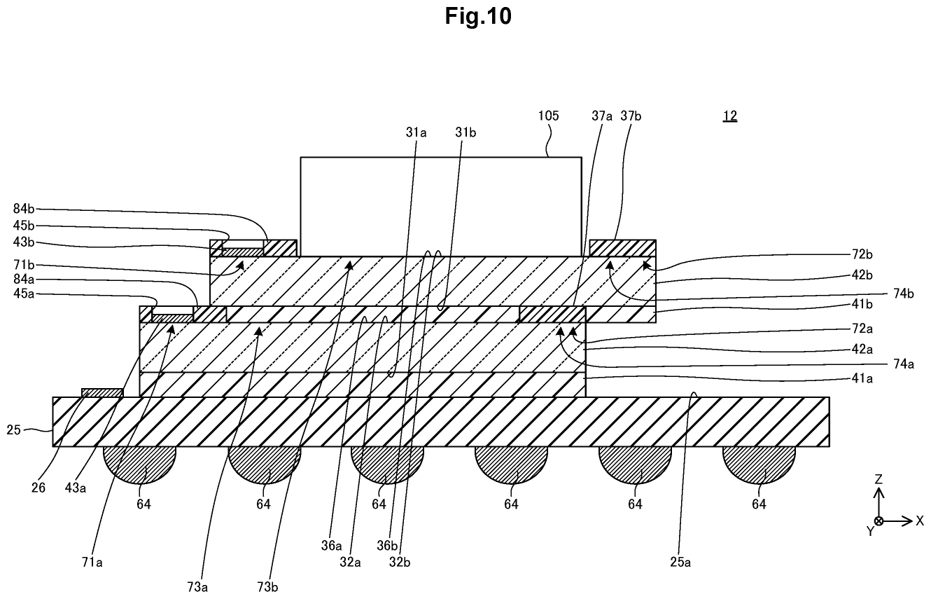

On the other hand, as shown in FIG. 10, in the semiconductor device 12, at a portion that is close to the edge of the semiconductor chip 42b and that is not pressed by the bonding collet 105, a step is formed by the high-level surface 37a of the PI film 84a and the low-level surface 36a of the semiconductor chip 42a.

Even when the end portion of the semiconductor chip 42b is turned upward, the step makes it possible to increase the possibility that the end portion of the semiconductor chip 42b and the high-level surface 37a of the PI film 84a get contact with each other. That is, even when the bonding collet 105 that does not press the whole of the upper plane 32b of the semiconductor chip 42b is used, it is possible to restrain the gap, the air bubble, the void, or the like from being formed between the semiconductor chip 42b and the semiconductor chip 42a. Furthermore, it is possible to reduce the risk of the transfer of the die attach film 41 to the semiconductor chip 42.

Further, a downward dented space can be formed by the low-level surface region 73a where the PI film 84a is not provided and the PI film 84a. Thereby, it is possible to keep the die attach film 41b in the space, and therefore, compared to the semiconductor device 90 (see FIG. 8), it is possible to reduce the interval between the semiconductor chips 42, and further to reduce the total height of the chip laminated body 40.

Further, compared to the first embodiment, the contact area between the PI film 84a and the die attach film 41b is increased by the downward dented space formed by the low-level surface region 73a where the PI film 84a is not provided and the PI film 84a. Accordingly, the adhesion strength between the semiconductor chip 42a and the semiconductor chip 42b is improved.

### First Modification

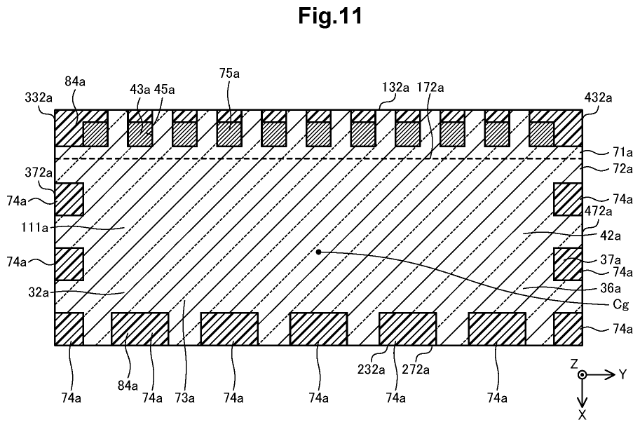

FIG. 11 is a plan view of a semiconductor chip according to a first modification of the second embodiment as viewed from above. As shown in FIG. 11, in the semiconductor chip 42a according to the first modification of the second embodiment, the low-level surface region 73a contacts with the sides 132a, 232a, 332a, and 432a of the plane 32a, in planar view of the plane 32a. The high-level surface region 74a is divided into a plurality of regions. That is, as shown in FIG. 11, the low-level surface region 73a is positioned between two high-level surface regions 74a.

Accordingly, even if the void is generated in the die attach film 41b when the semiconductor chip 42b is placed on the semiconductor chip 42a, it is possible to push the void out of the die attach film 41b through between the two high-level surface regions 74a.

### Second Modification

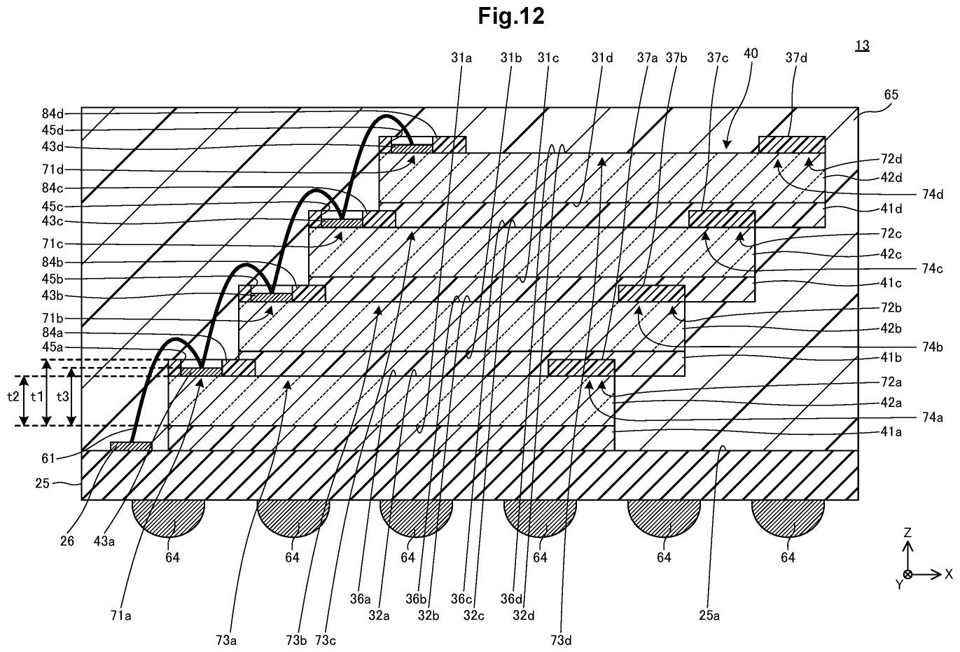

FIG. 12 is a schematic view showing a cross-section of a semiconductor device according to a second modification of the second embodiment as viewed laterally. The configuration in which the upper high-level surface 37a of the PI film 84a and the lower plane 31b of the semiconductor chip 42b contact with each other in the semiconductor device 12 shown in FIG. 6 has been described, but the present disclosure is not limited to this.

As shown in FIG. 12, in the semiconductor device 13, the die attach film 41b is provided between the upper high-level surface 37a of the PI film 84a and the lower plane 31b of the semiconductor chip 42b. Similarly, the die attach film 41c is provided between the upper high-level surface 37b of the PI film 84b and the lower plane 31c of the semiconductor chip 42c. Similarly, the die attach film 41d is provided between the upper high-level surface 37c of the PI film 84c and the lower plane 31d of the semiconductor chip 42d.

The semiconductor devices 12 and 13 are example, and for example, it is allowable to mix the configuration in which the upper high-level surface of the PI film and the lower plane of the semiconductor chip contact with each other and the configuration in which the die attach film is provided between the upper high-level surface of the PI film and the lower plane of the semiconductor chip.

### Third Modification

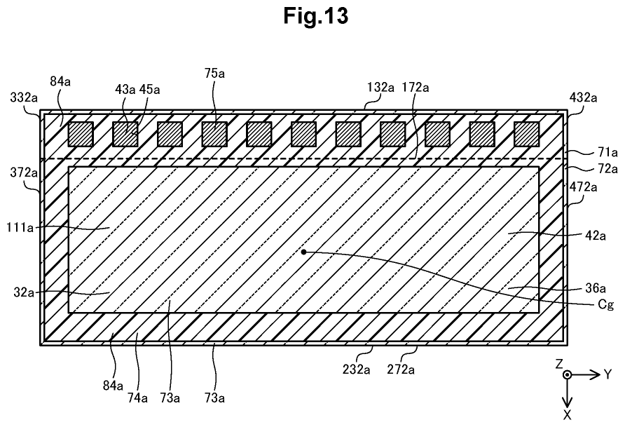

FIG. 13 is a plan view of a semiconductor chip according to a third modification of the second embodiment as viewed from above. The configuration in which the high-level surface region 74a contacts with the sides 132a, 232a, 332a, and 432a of the plane 32a in planar view of the plane 32a in the semiconductor device 12 shown in FIG. 6 and FIG. 7 has been described, but the present disclosure is not limited to this.

It is allowable to adopt a configuration in which the high-level surface region 74a does not contacts with the sides 132a, 232a, 332a, and 432a of the plane 32a in planar view of the plane 32a, as shown in FIG. 13. In the modification, the low-level surface 36a is positioned between the outer circumference of the high-level surface region 74a and the outer circumference of the plane 32a. It is allowable to adopt a configuration in which the high-level surface region 74a contacts with a part of the sides 132a, 232a, 332a, and 432a of the plane 32a in planar view of the plane 32a.

### Fourth Embodiment

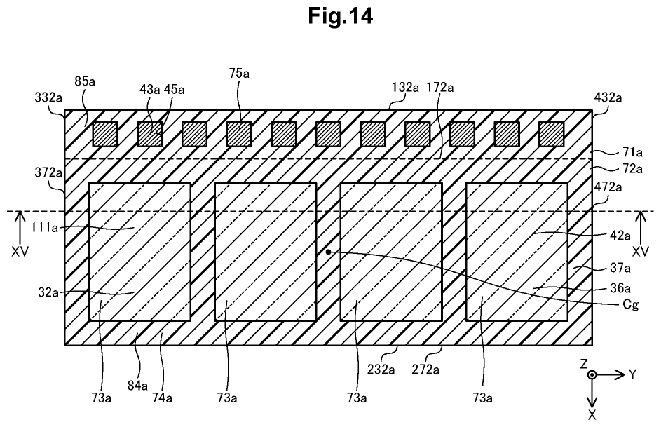

FIG. 14 is a plan view of a semiconductor chip according to a fourth modification of the second embodiment as viewed from above. The configuration in which the low-level surface region 73a is not divided in the semiconductor device 12 shown in FIG. 6 and FIG. 7 has been described, but the present disclosure is not limited to this.

As shown in FIG. 14, in the semiconductor chip 42a according to the fourth modification of the second embodiment, the low-level surface region 73a is divided into four regions. The low-level surface region 73a may be divided into two regions, three regions, or five or more regions.

The low-level surface region 73a shown in FIG. 14 does not include the gravity center Cg of the chip arrangement region 72a. It is allowable to adopt a configuration in which the low-level surface region 73a includes the gravity center Cg.

Among the four low-level surface regions 73a, the low-level surface region 73a positioned on the outermost side in the Y-axis−direction is provided, for example, at a position 150 μm or more away from the side 332a of the semiconductor chip 42a in the Y-axis+direction. The low-level surface region 73a positioned on the outermost side in the Y-axis+direction is provided, for example, at a position 150 μm or more away from the side 432a of the semiconductor chip 42a in the Y-axis−direction.

The four low-level surface regions 73a are provided, for example, at a position 150 μm or more away from the side 232a of the semiconductor chip 42a in the X-axis−direction. The four low-level surface regions 73a are provided, for example, at a position 150 μm or more away from the edge 172a of the chip arrangement region 72a in the X-axis+direction. The four low-level surface regions 73a are provided, for example, at a position 1 mm away from the chip electrodes 43a in the X-axis+direction.

For example, the four low-level surface regions 73a are formed by the photolithography processing described in FIG. 5B. For example, the four low-level surface regions 73a may be formed by a dicing for which the blade 103 shown in FIG. 5E is used. For example, this dicing is performed before the separation into a plurality of semiconductor chips 42 (S110).

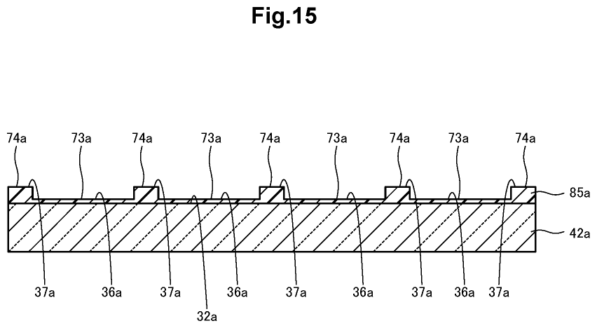

FIG. 15 is a cross-section view along cutting-plane line XV-XV shown in FIG. 14. The configuration in which the plane 32a is exposed at the opening of the PI film 85a has been described, but the present disclosure is not limited to this. It is allowable to adopt a configuration in which the PI film 85a is not opened at the low-level surface region 73a and the PI film 85a having a low-level surface 36a lower than the high-level surface 37a of the PI film 85a at the high-level surface region 74a is arranged at the low-level surface region 73a as shown in FIG. 15.

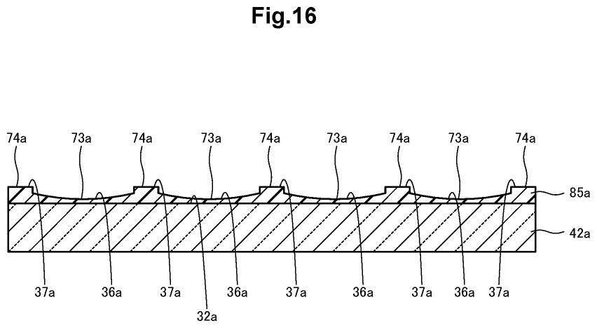

It is allowable to adopt a configuration in which the low-level surface 36a has a round shape that is dented downward, as shown in FIG. 16.

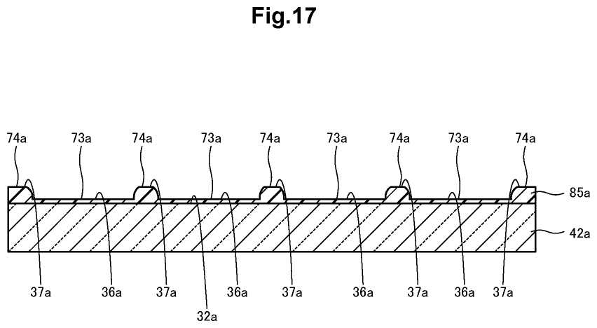

It is allowable to adopt a configuration in which round chamfering is performed to the step between the high-level surface 37a and the low-level surface 36a, as shown in FIG. 17.

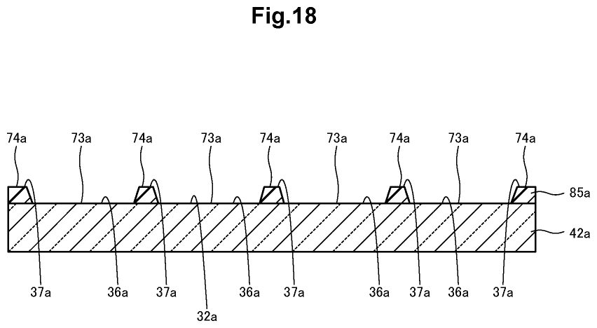

It is allowable to adopt a configuration in which C chamfering is performed to the step between the high-level surface 37a and the low-level surface 36a, as shown in FIG. 18. In the semiconductor chip 42a shown in FIG. 18, the PI film 85a is opened and the plane 32a is exposed, at the low-level surface region 73a.

(a) In the embodiment, the configuration in which the Pi film 44 at the lamination region 34 is fully removed has been described, but the present disclosure is not limited to this. For example, it is allowable to adopt a configuration in which the PI film 44 lower than the PI film 44a at the bonding region 33a is arranged at the lamination region 34a in the semiconductor chip 42a. In other words, it is allowable to adopt a configuration in which the PI film 44 having a thickness smaller than the thickness of the PI film 44a at the bonding region 33a is arranged at the lamination region 34a.

(b) In the embodiment, the configuration in which the chip laminated body 40 is arranged on the wiring substrate 25 has been described, but the present disclosure is limited to this. It is allowable to adopt a configuration in which the chip laminated body 40 is arranged on or above a lead frame.

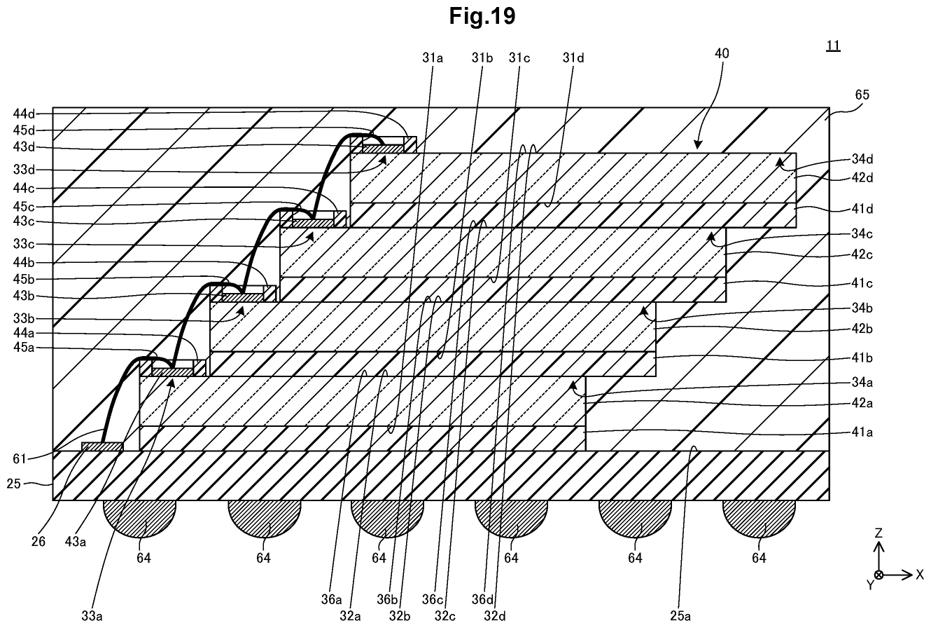

(c) In the embodiment, the configuration in which the bonding wires 61 do not abut on the PI films 44a, 44b, 44c, and 44d has been described, but the present disclosure is not limited to this. It is allowable to adopt a configuration in which the bonding wires 61 abut on the PI films 44a, 44b, 44c, and 44d, as in the case of a semiconductor device 11 (an example of the “semiconductor memory device”) shown in FIG. 19, which is a modification of the semiconductor device 10. It is allowable to adopt a configuration in which the bonding wires 61 abut on parts of the PI films 44a, 44b, 44c, and 44d.

(d) In the embodiment, the configuration in which the four semiconductor chips 42 are laminated in the chip laminated body 40 has been described, but the present disclosure is not limited to this. It is allowable to adopt a configuration in which two semiconductor chips 42, three semiconductor chips 42, or five or more semiconductor chips 42 are laminated in the chip laminated body 40.

(e) In the embodiment, the configuration in which the solder balls 64 are arranged on the lower plane of the wiring substrate 25 has been described, but the present disclosure is not limited to this. It is allowable to adopt a configuration in which the lower plane of the wiring substrate 25 has an LGA (Land Grid Array) in which plane electrode pads are arrayed in a reticular pattern.

(f) A semiconductor device according to the present disclosure includes:
a substrate that includes an external terminal;
a first semiconductor chip on or above which a first bonding pad is arranged;
a second semiconductor chip that is arranged between the substrate and the first semiconductor chip, the second semiconductor chip on or above which a second bonding pad and a first insulating film being arranged;
a bonding wire that connects the substrate, the first bonding pad, and the second bonding pad; and
a sealing resin that seals at least the first semiconductor chip, the second semiconductor chip, and the bonding wire, wherein:
the second semiconductor chip includes a smooth first surface that faces the substrate, and a second surface that faces the first semiconductor chip; and
the second surface includes
   a first bonding region where the second bonding pad and the first insulating film are arranged, and
   a first lamination region that is thinner than the thickness of the second semiconductor chip including the first insulating film, the first semiconductor chip being arranged at at least a part of the first lamination region.

(g) A semiconductor device according to the present disclosure is a semiconductor device including:
a substrate that includes an external terminal;
a first semiconductor chip; and
a second semiconductor chip that is arranged between the substrate and the first semiconductor chip, the second semiconductor chip on or above which a first insulating film being arranged, wherein:
the second semiconductor chip includes a first surface that faces the substrate, and a second surface on an opposite side of the first surface;
the second surface includes
   a first chip arrangement region where the first semiconductor chip is arranged,
   a high-level surface region that includes a high-level surface, at least a part of the high-level surface region overlapping with the first chip arrangement region, and
   a low-level surface region that is adjacent to the high-level surface region and that includes a third low-level surface lower than the high-level surface, at least a part of the low-level surface region overlapping with the first chip arrangement region; and
the first insulating film is arranged at least at the high-level surface region.

(h) The semiconductor device according to (g), wherein
the low-level surface region includes a gravity center of the first chip arrangement region.

(i) The semiconductor device according to (h), wherein
the high-level surface region is positioned that being closer to an edge of the first chip arrangement region than to the gravity center.

(j) The semiconductor device according to (g), wherein
the low-level surface region contacts with an edge of the second surface.

(k) The semiconductor device according to (i), wherein
the high-level surface region is divided into a plurality of regions.

(l) The semiconductor device according to (g), wherein
the high-level surface region contacts with an edge of the second surface in planar view of the second surface.

(m) The semiconductor device according to (g), wherein
the low-level surface region is divided into a plurality of regions.

(n) The semiconductor device according to (g), wherein;
a first bonding pad is arranged on or above the first semiconductor chip;
an adjacent region that is adjacent to the first chip arrangement region includes a second bonding pad and the first insulating film; and
the semiconductor device further comprises
a bonding wire that connects the substrate, the first bonding pad, and the second bonding pad, and
a sealing resin that seals at least the first semiconductor chip, the second semiconductor chip, and the bonding wire.

(o) The semiconductor device according to (g), wherein
the surface of the first insulating film is formed so as to be higher than a surface of the second bonding pad.

(p) The semiconductor device according to (g), wherein:
the first semiconductor chip includes a third surface that faces the substrate across the second semiconductor chip; and
the semiconductor device further comprises
an adhesion layer that performs adhesion between at least a part of the low-level surface region on the second surface and at least a part of the third surface.

(q) The semiconductor device according to (g), wherein:
a second insulating film is further arranged on or above the first semiconductor chip;
the first semiconductor chip includes a third surface that faces the substrate across the second semiconductor chip, and a fourth surface on an opposite side of the third surface; and
the fourth surface includes
   a second chip arrangement region where a third semiconductor chip is arranged,
   a high-level surface region that includes a high-level surface, at least a part of the high-level surface region overlapping with the second chip arrangement region, and
   a low-level surface region that is adjacent to the high-level surface region and that has a fourth low-level surface formed that being lower than the high-level surface, at least a part of the low-level surface region overlapping with the second chip arrangement region; and
the second insulating film is arranged at least at the high-level surface region.

The embodiments have been described above with reference to specific examples. The present disclosure is not limited to the specific examples. Examples in which a person skilled in the art appropriately has performed design change to the specific examples are also included in the scope of the present disclosure, as long as the characteristics of the present disclosure are included. The elements included in the above specific examples, the dispositions thereof, the conditions thereof, the shapes thereof, and the like are not limited to those in the examples, and can be appropriately changed. The combinations of the elements included in the above specific examples can be appropriately changed, as long as there is no technical inconsistency.

1. A semiconductor device comprising:
a substrate that includes an external terminal;
a first semiconductor chip on or above which a first bonding pad is arranged;
a second semiconductor chip that is arranged between the substrate and the first semiconductor chip, the second semiconductor chip on or above which a second bonding pad and a first insulating film being arranged;
a bonding wire that connects the substrate, the first bonding pad, and the second bonding pad; and
a sealing resin that seals at least the first semiconductor chip, the second semiconductor chip, and the bonding wire, wherein:
the second semiconductor chip includes a first surface that faces the substrate, and a second surface on an opposite side of the first surface; and
the second surface includes
a first bonding region where the second bonding pad and the first insulating film are arranged, and
a first lamination region that has a first low-level surface formed that being lower than a surface of the first insulating film, the first semiconductor chip being arranged on or above at least a part of the first low-level surface.

2. The semiconductor device according to claim 1, wherein
the surface of the first insulating film is formed that being higher than a surface of the second bonding pad.

3. The semiconductor device according to claim 1, wherein:
the first semiconductor chip includes a third surface that faces the substrate across the second semiconductor chip; and
the semiconductor device further comprises
an adhesion layer that performs adhesion between at least a part of the first lamination region on the second surface and at least a part of the third surface.

4. The semiconductor device according to claim 1, wherein:
a second insulating film is further arranged on or above the first semiconductor chip;
the first semiconductor chip includes a third surface that faces the substrate across the second semiconductor chip, and a fourth surface on an opposite side of the third surface; and
the fourth surface includes
a second bonding region where the first bonding pad and the second insulating film are arranged, and
a second lamination region that has a second low-level surface formed that being lower than a surface of the second insulating film, a third semiconductor chip being arranged on or above at least a part of the second low-level surface.

5. The semiconductor device according to claim 1, wherein:
the second surface has a rectangular shape; and
the first bonding region is positioned that being closer to one side of two facing sides of the rectangular shape than to the other side.

6. The semiconductor device according to claim 5, wherein
the first bonding region abuts on the one side.

7. A semiconductor device comprising:
a substrate that includes an external terminal;
a first semiconductor chip; and
a second semiconductor chip that is arranged between the substrate and the first semiconductor chip, the second semiconductor chip on or above which a first insulating film being arranged, wherein:
the second semiconductor chip includes a first surface that faces the substrate, and a second surface on an opposite side of the first surface;
the second surface includes
a first chip arrangement region where the first semiconductor chip is arranged,
a high-level surface region that includes a high-level surface, at least a part of the high-level surface region overlapping with the first chip arrangement region, and
a low-level surface region that is adjacent to the high-level surface region and that includes a third low-level surface lower than the high-level surface, at least a part of the low-level surface region overlapping with the first chip arrangement region; and
the first insulating film is arranged at least at the high-level surface region.

8. The semiconductor device according to claim 7, wherein
the low-level surface region includes a gravity center of the first chip arrangement region.

9. The semiconductor device according to claim 8, wherein
the high-level surface region is positioned that being closer to an edge of the first chip arrangement region than to the gravity center.

10. The semiconductor device according to claim 7, wherein
the low-level surface region contacts with an edge of the second surface.

11. The semiconductor device according to claim 9, wherein
the high-level surface region is divided into a plurality of regions.

12. The semiconductor device according to claim 7, wherein
the high-level surface region contacts with an edge of the second surface in planar view of the second surface.

13. The semiconductor device according to claim 7, wherein
the low-level surface region is divided into a plurality of regions.

14. The semiconductor device according to claim 7, wherein
a surface of the first insulating film is formed that being higher than a surface of the second bonding pad.

15. The semiconductor device according to claim 7, wherein:
the first semiconductor chip includes a third surface that faces the substrate across the second semiconductor chip; and
the semiconductor device further comprises
an adhesion layer that performs adhesion between at least a part of the low-level surface region on the second surface and at a least a part of the third surface.

16. A method for manufacturing a semiconductor device, the method comprising:
forming an insulating film on or above a first plane of a semiconductor wafer on or above which a plurality of circuits is formed, the plurality of circuits being included in a plurality of semiconductor chips, respectively;
forming a second surface for each of the circuits, the second surface being a part of the first surface and including a bonding region and a lamination region, a bonding pad and a part of the insulation film being arranged at the bonding region, the lamination region having a low-level surface formed that being lower than a surface of the insulating film, the semiconductor chip configured to be arranged on or above at least a part of the low-level surface;
forming the plurality of semiconductor chips by dicing the semiconductor wafer;
disposing a second semiconductor chip on or above a substrate that includes an external terminal, the second semiconductor chip being one of the semiconductor chips;
disposing a first semiconductor chip at a first lamination region, the first semiconductor chip being another one of the semiconductor chips, the first lamination region being the lamination region on the second semiconductor chip;
connecting the substrate, a first bonding pad, and a second bonding pad, by a bonding wire, the first bonding pad being the bonding pad of the first semiconductor chip, the second bonding pad being the bonding pad of the second semiconductor chip; and
sealing at least the first semiconductor chip, the second semiconductor chip, and the bonding wire, by a sealing resin.

17. The method for manufacturing the semiconductor device according to claim 16, wherein
the forming the second surface for each of the circuits includes:
removing the insulating film on or above a portion of the bonding region, by photolithography processing of the insulating film, the portion being a portion where the bonding pad is formed; and
forming the bonding pad on or above the portion.

18. The method for manufacturing the semiconductor device according to claim 16, wherein
the forming the second surface for each of the circuits includes
removing the insulating film at the lamination region, by photolithography processing of the insulating film.

19. The method for manufacturing the semiconductor device according to claim 16, wherein
the forming the insulating film on or above the first plane includes
forming the insulating film with a surface higher than a surface of the bonding pad.

20. The method for manufacturing the semiconductor device according to claim 16, wherein:
the first semiconductor chip includes a third surface that faces the substrate across the second semiconductor chip; and
the method for manufacturing the semiconductor device further comprises
performing adhesion by an adhesion layer between at least a part of the first lamination region on the second surface and at least a part of the third surface.
